(19) United States
(12) Patent Application Publication
(10) Pub. No.: US 2015/0275396 A1
(43) Pub. Date: Oct. 1, 2015

(54) HIGH PRESSURE SINGLE CRYSTAL DIAMOND ANVILS

(71) Applicants: Reinhard Boehler, Potomac, MD (US); Yarden Tsach, Rockville, MD (US)

(72) Inventors: Reinhard Boehler, Potomac, MD (US); Yarden Tsach, Rockville, MD (US)

(21) Appl. No.: 14/668,192

(22) Filed: Mar. 25, 2015

Related U.S. Application Data
(60) Provisional application No. 61/970,483, filed on Mar. 26, 2014.

(51) Int. Cl. C30B 29/04; C30B 25/02

(52) U.S. Cl. CPC C30B 29/04; C30B 25/02

(57) ABSTRACT

A high pressure anvil is provided. The high pressure anvil includes a two-strata body including a first body grown by chemical vapor deposition and a second layer grown by an epitaxy deposition method.

### CROSS REFERENCE TO RELATED APPLICATION

This application is a traditional application of and claims priority to U.S. Provisional Patent Application Ser. No. 61/970,483, filed Mar. 26, 2014 entitled HIGH PRESSURE SINGLE CRYSTAL DIAMOND ANVILS.

### BACKGROUND OF THE INVENTION

### Field of Invention

The following disclosure describes a layered body of a single crystal diamond high pressure anvil (hereinafter “high pressure anvil”) grown in a Chemical Vapor Deposition method.

### SUMMARY OF THE INVENTION

A layered high pressure anvil has multiple applications including, high pressure cells, sensors for magnetic field, biological sensors and more. The high pressure anvil body is created using a high nitrogen seed plate to create two strata; a low nitrogen first body (hereinafter “first body”) with a thickness of between about 100 micron and 3 mm. That is, the first body is created in a low nitrogen atmosphere. A very low nitrogen second layer (hereinafter “second layer”) with virtually no nitrogen and a thickness of between about 100 nm and 2 mm is then grown upon the first body. That is, the second layer is created in an atmosphere with virtually no nitrogen. In an exemplary embodiment, the second layer is created in an atmosphere with a Nitrogen concentration of less than about 100 parts-per-billion.

The second layer is created by epitaxial growth conditions defined so the specified properties of the utilized application are met. That is, in an exemplary embodiment, the growth conditions create a second layer with a two-phonon Raman peak near 2664 cm⁻¹ with very high signal to background ratio as shown in FIG. 2. Extended Raman spectra of several type diamond anvils are shown in FIG. 3. The signal to background ratio of that peak of the secondary layer is comparable to synthetic ultra-pure HP-HT diamond as shown in FIG. 3. The intensity of the two-phonon (second order) Raman peak at 2664 cm⁻¹ is at least 2.5 times higher than the background intensity (for example at 2800 cm⁻¹)

Conversely, the seed plate has non-defined or inferior properties achieved by faster growth and non-controlled growth environment. The seed plate is being used as a seed layer for the first body. Following the creation of the first body and the second layer, collectively, the “high pressure anvil is separated from the seed plate for use in a high pressure anvil cell. The high pressure anvil is shown in FIG. 5.

Further, the high pressure anvil is generally cylindrical in lateral cross-section. It is understood that the crystal structure includes a number of planar surfaces that from the generally cylindrical lateral cross-section. That is, the “generally cylindrical” cross-sectional shape includes a number of generally straight line segments that form a generally circular shape. As shown in FIG. 5, the high pressure anvil includes a generally planar support side and a test side. The second layer is disposed on the test side. The test side, in an exemplary embodiment, has a smaller cross-sectional area than the support side.

As a result, the overall performance of the device utilizing the high pressure anvil is comparable or superior to the currently available high pressure anvil material, while the overall rate of growth of the high pressure anvil is high and the cost of the high pressure anvil is kept low.

### BRIEF DESCRIPTION OF THE DRAWINGS

A full understanding of the invention can be gained from the following description of the preferred embodiments when read in conjunction with the accompanying drawings in which:

FIG. 1 is a side view of a seat assembly.

FIG. 2 is a graph showing the Raman Spectrum of a layer with a low nitrogen content.

FIG. 3 is a graph showing the Raman Spectrum of the layer structure with best low nitrogen content of an ultra-low fluorescence layered anvil compared to other anvil materials excited at 532 nm.

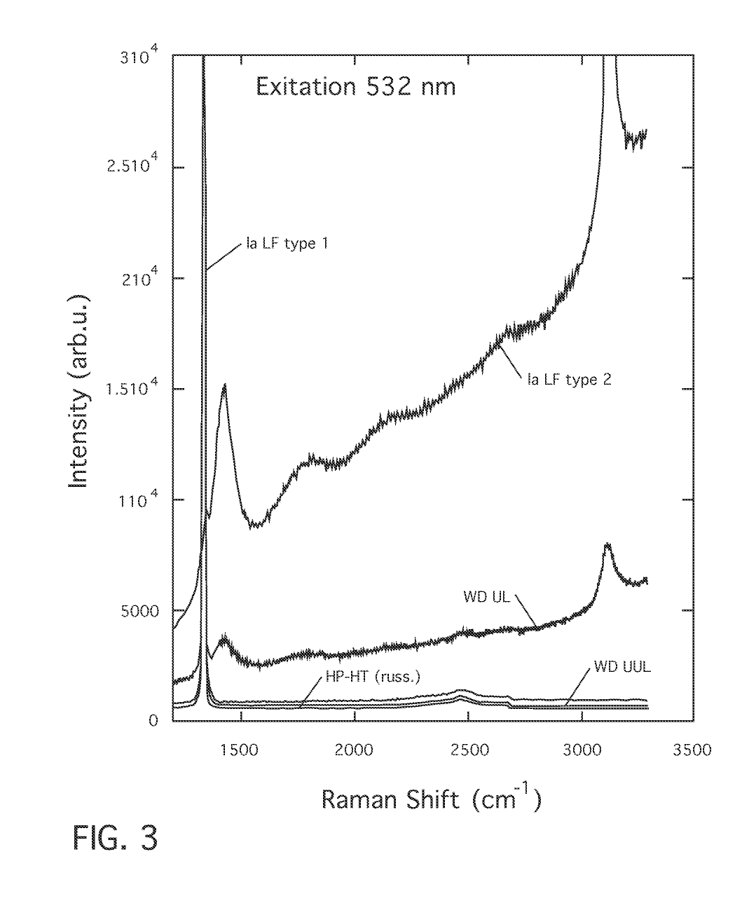

FIG. 4 is a graph showing a Comparison of the two-phonon Raman peak of WD UUL low nitrogen layer with other anvil materials (excitation wavelength is 532 nm).

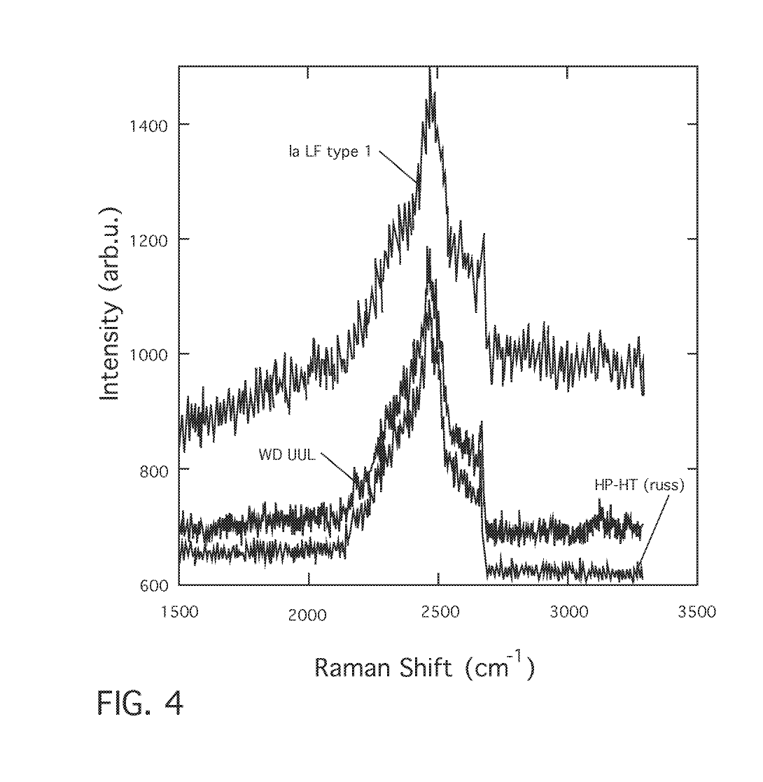

FIG. 5 is a schematic side view of an anvil.

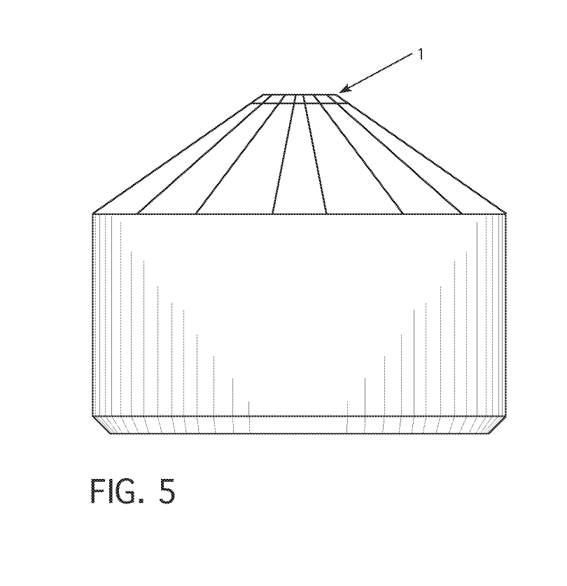

FIG. 6 is a schematic side view of an anvil assembly with a radiation probe.

FIG. 7 is a side view of a seat. FIG. 7A is a detail side view of the seat.

### DESCRIPT ON OF THE PREFERRED EMBODIMENTS

### High Pressure Anvil Cells:

The following shape of an anvil is devised for the purpose of a high optical performance diamond anvil:

A high pressure anvil cell utilizes two high pressure anvils disposed in opposition to each other. High pressure anvil cells are being used for optically characterizing the properties of substances under high pressure. The following disclosure describes a method for utilizing a high pressure anvil as a diamond anvil. The second layer is utilized to perform high quality optical characterization with a need for extremely low fluorescents. The characterization is utilizing a laser probe that is focused to the sample locked under high pressure in between two high pressure anvils with low Nitrogen layers. The focusing is done in high numerical aperture allowing focusing on the sample only. A second layer with a thickness of 100 micrometer is sufficient to avoid florescence from the bulk low nitrogen anvil, i.e. the first body.

### High Pressure Anvils Seats:

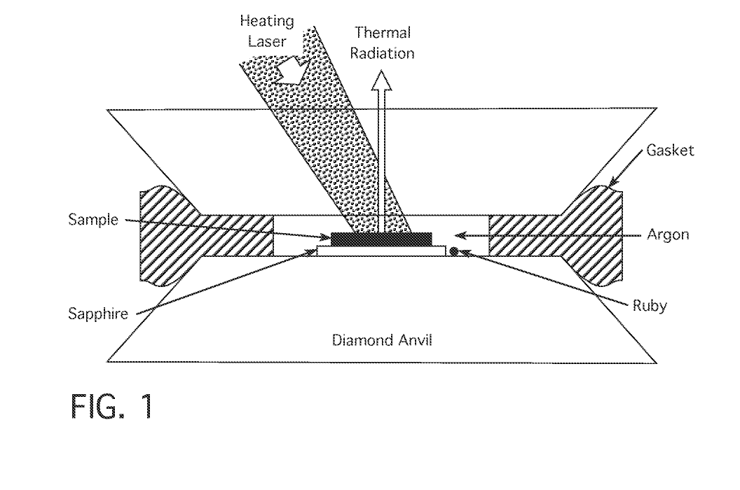

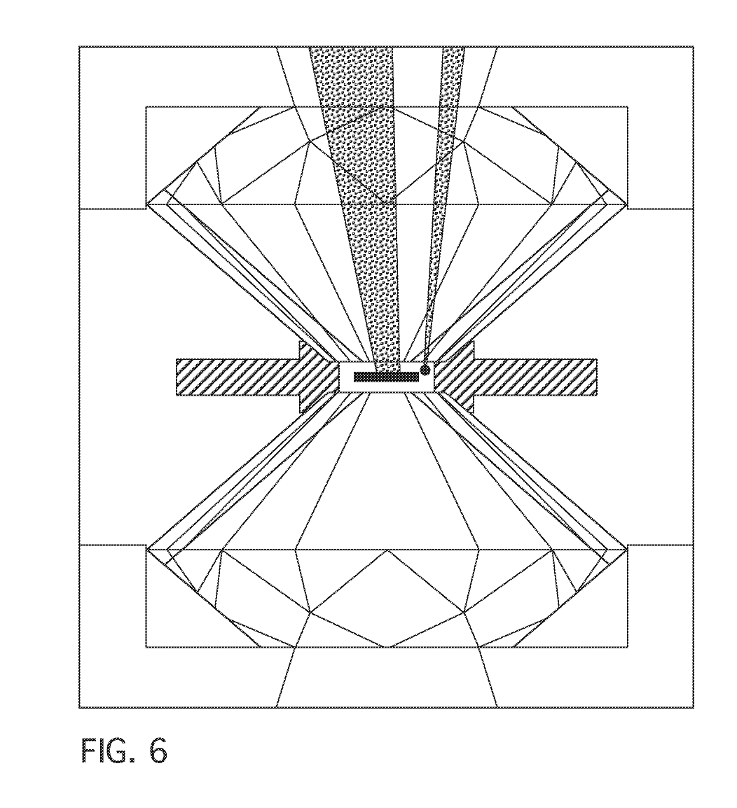

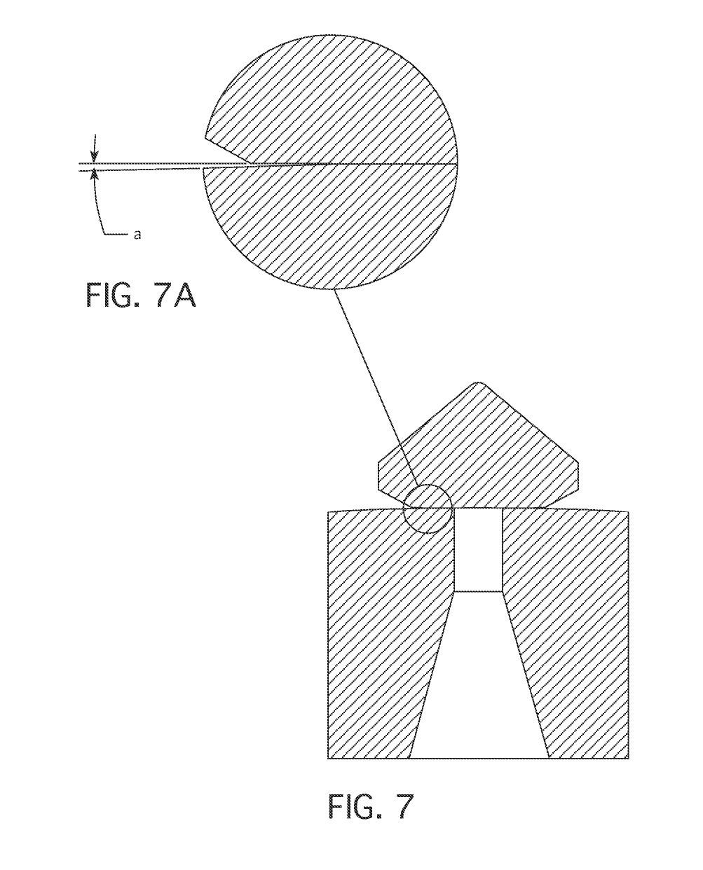

The high pressure anvils are placed on a seat assembly that supports the high pressure anvils under high pressure and provides an opening for a probe to reach the sample, see FIGS. 1 and 6. That is, a seat assembly includes two seats, each of which supports a high pressure anvil. The seats are substantially similar and only one will be described. As shown in FIG. 7, the seat includes a body defining a passage. The body has an anvil support side and a distal side. The passage extends between the anvil support side and the distal side. The anvil support side defines an anvil seat. The anvil seat includes a substantially planar portion and an inclined portion. Generally, the inclined portion extends about the planar portion. Further, the passage extends generally, centrally through the planar portion. In an exemplary embodiment, e planar portion, inclined portion and passage are generally cylindrical.

The design, and more specifically the surface area between the diamond and the metal of the seat controls the force distribution from the diamond to the metal, therefore, controls at which pressure loading point the metallic seat will yield. Plastic strain in the metallic seat is not desirable as the metallic seat when yielding may cause a side force to the stone that results in tensile force applied to the diamond. Suggested is a design to avoid the plastic deformation in the metallic seat. See FIG. 7. That is, a high pressure anvil is disposed on the planar portion with the central axis of the high pressure anvil generally aligned, i.e. in line with, the longitudinal axis of the passage. The planar portion has a diameter that is smaller than the diameter of the high pressure anvil support side. In this configuration, the outer perimeter of the high pressure anvil support side extends over the inclined portion. When the high pressure anvil cell is not in use, i.e. when the high pressure anvil cell is not under pressure, the inclined portion is spaced from the inclined portion high pressure anvil support side. When force is applied to the anvils, the contact area between anvil and seat thus increases to a point where the entire anvil area is in contact with the seat. Areas and angles are calculated such that at the highest force the seat material is still behaving elastically (e.g. without plastic flow). Without the inclination on the seat, the anvil fails prematurely because of the high tensile stresses at the edge of the anvil and the given low tensile strength of the high pressure anvil.

As is known, the sample is disposed between two high pressure anvils configured as a high pressure anvil cell. A laser is shown through the seat body passage upon the sample and the reflected light is analyzed, as is known. Further, a ruby may be disposed in the anvil test space for use in measuring pressure via a secondary laser, also as known.

FIG. 1, shows a typical high pressure cell for the purpose of high pressure materials synthesis and characterization. The sample is pressed between two diamond anvils and probed optically with radiation that moves through the diamond anvil.

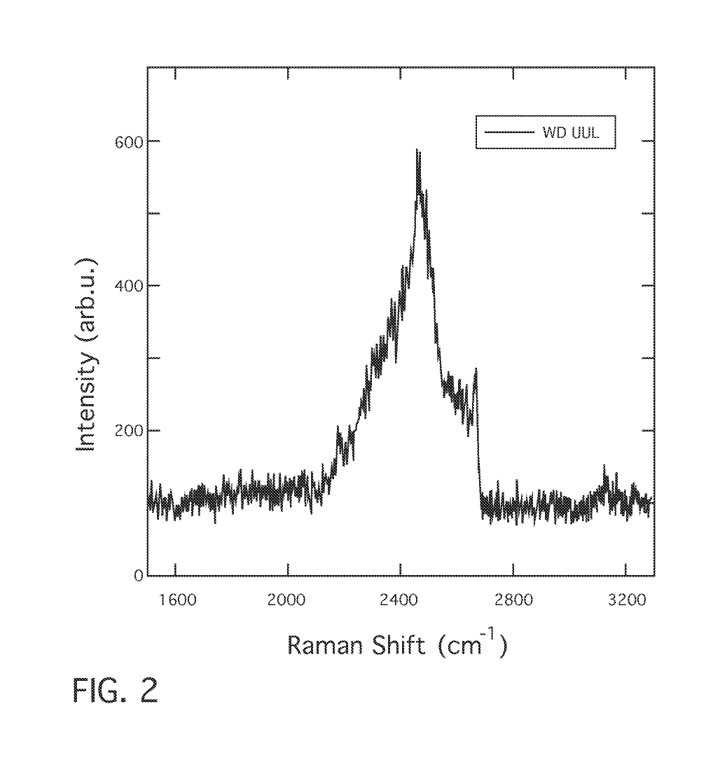

FIG. 2 shows the Raman Spectrum of layer with best low nitrogen content of an ultra-low fluorescence layered anvil. The intensity of the two-phonon (second order) Raman peak at 2664 cm⁻¹ is at least 2.5 times higher than the background intensity (for example at 2800 cm⁻¹). The excitation laser wavelength is 532 nm.

FIG. 7 shows the seat that supports the diamond anvil. The center area is in contact with the diamond bottom surface before loading. The inclination in the metallic or ceramic seat allows full contact at the highest pressure loaded at the tip of the diamond anvil.

What is claimed is:

1. A high pressure anvil comprising a two-strata body including a first body grown by chemical vapor deposition and a second layer grown by an epitaxy deposition method.
